(19) United States
(12) Patent Application Publication
(10) Pub. No.: US 2025/0330150 A1
(43) Pub. Date: Oct. 23, 2025

(54) LADDER FILTER

(71) Applicant: Murata Manufacturing Co., Ltd., Nagaokakyo-shi (JP)

(72) Inventor: Kenichi UESAKA, Nagaokakyo-shi (JP)

(21) Appl. No.: 19/252,437

(22) Filed: Jun. 27, 2025

Related U.S. Application Data
(63) Continuation of application No. PCT/JP2023/045863, filed on Dec. 21, 2023.

(30) Foreign Application Priority Data
Dec. 29, 2022 (JP) 2022-212861

(51) Int. Cl. H03H 9/64

(52) U.S. Cl. CPC H03H 9/6483; H03H 9/6479

(57) ABSTRACT

A ladder filter includes serial arm resonators in a serial arm and parallel arm resonators in parallel arms. A resonant frequency of at least one of the serial arm resonators is lower than a relevant band. An anti-resonant frequency of at least one of the parallel arm resonators is higher than the relevant band. The ladder filter includes one or more capacitances provided in at least one of the serial arm and the parallel arms. The capacitances are not provided in one or more of the parallel arms in which the one or more parallel arm resonators are provided.

### CROSS REFERENCE TO RELATED APPLICATIONS

This application claims the benefit of priority to Japanese Patent Application No. 2022-212861 filed on Dec. 29, 2022 and is a Continuation Application of PCT Application No. PCT/JP2023/045863 filed on Dec. 21, 2023. The entire contents of each application are hereby incorporated herein by reference.

### BACKGROUND OF THE INVENTION

### 1. Field of the Invention

The present invention relates to ladder filters and, in more detail, ladder filters each including a serial arm resonator and a parallel arm resonator.

### 2. Description of the Related Art

A ladder surface acoustic wave filter described in Japanese Unexamined Patent Application Publication No. 2001-156586 includes a plurality of resonators (serial arm resonators) provided in a serial arm and a plurality of resonators (parallel arm resonators) provided in a plurality of parallel arms. In the ladder surface acoustic wave filter, the anti-resonant frequency of the parallel arm resonators is matched with the resonant frequency of the serial arm resonators, and a filter having a pass band with the matched frequency defining and functioning as a center frequency is thus provided.

However, in a case where a filter having an attenuation characteristic near a pass band through which a signal included in a relevant band for the filter passes is formed by using resonators having a wider frequency interval between a resonant frequency and an anti-resonant frequency than the relevant band, it is not possible on occasions to ensure attenuation near the pass band in the filter as in Japanese Unexamined Patent Application Publication No. 2001-156586, the filter having the anti-resonant frequency of a parallel arm resonator that is matched with the resonant frequency of a serial arm resonator. The pass band of the filter is thus excessively wider than the relevant band in some cases. The above described “relevant band” denotes the communication band of a signal passing through the filter. In this case, setting the resonant frequency of the parallel arm resonator high and the resonant frequency of the serial arm resonator low to ensure the attenuation near the pass band causes the attenuation characteristic to be improved but causes the impedance characteristics of the pass band of the filter to be inductive, thus causing the reflection characteristic of the filter to be deteriorated.

### SUMMARY OF THE INVENTION

Example embodiments of the present invention provide ladder filters that each achieve both pass band narrowing and reflection characteristic improvement.

A ladder filter according to an example embodiment of the present invention includes one or more serial arm resonators and one or more parallel arm resonators. The one or more serial arm resonators are provided in a serial arm connecting a first end and a second end of the ladder filter. The one or more parallel arm resonators are provided in a plurality of parallel arms connecting the serial arm and ground. A frequency interval between a resonant frequency and an anti-resonant frequency of each of the one or more serial arm resonators and the one or more parallel arm resonators is wider than a relevant band. The resonant frequency of at least one serial arm resonator of the one or more serial arm resonators is lower than the relevant band. The anti-resonant frequency of at least one parallel arm resonator of the one or more parallel arm resonators is higher than the relevant band. The ladder filter further includes one or more capacitances provided in at least one arm of a plurality of arms including the serial arm and the plurality of parallel arms and not connected in parallel to any of the one or more series are resonators and the one or more parallel arm resonators. The one or more capacitances are not provided in one or more parallel arms of the plurality of parallel arms in which the one or more parallel arm resonators are provided.

A ladder filter according to another example embodiment of the present invention includes a serial arm connecting a first end and a second end of the ladder filter, and a plurality of parallel arms connected between the serial arm and ground. Points of connection with the plurality of parallel arms are defined as a plurality of branch points included in the serial arm. The serial arm includes a plurality of serial arm sections. The plurality of serial arm sections include a first section between the first end and a first branch point of the plurality of branch points in the serial arm and that is adjacent to the first end, a second section between the second end and a second branch point of the plurality of branch points in the serial arm and that is adjacent to the second end, and a third section between two adjacent branch points of the plurality of branch points. The ladder filter includes one or more capacitances provided in at least one of the plurality of serial arm sections and the plurality of parallel arms and not connected in parallel to any resonators, and one or more resonators provided in a remaining one or more of the plurality of serial arm sections and the plurality of parallel arms. A frequency interval between a resonant frequency and an anti-resonant frequency of the one or more resonators is wider than a relevant band. The resonant frequency of at least one serial arm resonator of one or more serial arm resonators defining and functioning as one or more of the resonators and provided in the serial arm is lower than the relevant band. The anti-resonant frequency of at least one parallel arm resonator of one or more parallel arm resonators defining and functioning as one or more of the resonators and provided in the parallel arms is higher than the relevant band.

The ladder filters according to example embodiments of the present invention each achieve both of pass band narrowing and reflection characteristic improvement.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a ladder filter according to an example embodiment of the present invention.

FIG. 2 is a plan view of a ladder filter according to an example embodiment of the present invention.

FIG. 3 is a circuit diagram of ladder filters according to Comparative Examples 1 and 2.

FIG. 4 is a graph illustrating impedance characteristics in Comparative Example 1.

FIG. 5 is a graph illustrating impedance characteristics in Comparative Example 2.

FIG. 6 is a graph illustrating impedance characteristics of a ladder filter according to an example embodiment of the present invention.

FIG. 7 is a graph illustrating respective attenuation characteristics of the ladder filter according to Comparative Example 1, the ladder filter according to Comparative Example 2, and a ladder filter according to an example embodiment of the present invention.

### DETAILED DESCRIPTION OF THE EXAMPLE EMBODIMENTS

Example embodiments of the present invention are described in detail below with reference to the drawings.

### EXAMPLE EMBODIMENTS

### (1) Overview of Ladder Filter

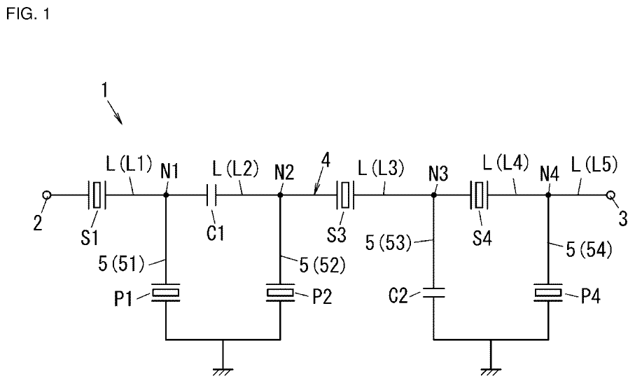

A ladder filter 1 according to an example embodiment will be described with reference to FIGS. 1 to 7.

The ladder filter 1 is, for example, a ladder surface acoustic wave filter. The ladder filter 1 is used for, for example, a radio frequency module of a communication device. The ladder filter 1 is usable as one of a reception filter, a transmission filter, and a transmission/reception filter that are provided in a reception path or a transmission path in the radio frequency module and that allows a frequency component corresponding to the relevant band of a radio frequency signal flowing through the reception path or the transmission path to pass. The above-described “relevant band” is a communication band of a signal passing through the ladder filter 1 and is a frequency band specified by communication standards. In the present example embodiment, the relevant band is, for example, Band30Rx (about 2350 MHz to about 2360 MHz).

It is assumed that the relevant band of the ladder filter 1 is, for example, a comparatively narrow band (for example, Band30Rx). However, the relevant band of the ladder filter 1 is not limited to the comparatively narrow band. The ladder filter 1 has a configuration with a pass band narrowed for the relevant band.

The following explanation is provided on the assumption that the ladder filter 1 is, for example, a reception filter.

### (2) Circuit Configuration of Ladder Filter

As illustrated in FIG. 1, the ladder filter 1 includes a first end 2, a second end 3, a serial arm 4, a plurality of (in the example in FIG. 1, four) parallel arms 5 (51 to 54), one or more (in the example in FIG. 1, two) capacitances (a capacitance C1 (first capacitance) and a capacitance C2 (second capacitance)), one or more (in the example in FIG. 1, three) serial arm resonators S1, S3, and S4, and one or more (in the example in FIG. 1, three) parallel arm resonators P1, P2, and P4.

The first end 2 is, for example, an input end to which a radio frequency signal is input. In a state where the radio frequency module includes the ladder filter 1, the first end 2 is connected to, for example, a signal path extending to an antenna terminal. The second end 3 is, for example, an output end from which a radio frequency signal having passed through the ladder filter 1 is output. In the state where the radio frequency module includes the ladder filter 1, the second end 3 is connected to, for example, a signal path extending to the output end of the radio frequency module.

The serial arm 4 is an electrical path connecting the first end 2 and the second end 3. The plurality of parallel arms 5 (51 to 54) are each an electrical path connecting the serial arm 4 and ground. The plurality of parallel arms 51 to 54 correspond to a plurality of branch points N1 to N4 of the serial arm 4 on a one-to-one basis and each connects a corresponding one of the branch points and ground.

The one or more (in the example in FIG. 1, two) capacitances C1 and C2 are provided in one or more arms (two arms that are the serial arm 4 and the parallel arm 53 in the example in FIG. 1 of the plurality of arms including the serial arm 4 and the plurality of parallel arms 5). In more detail, the capacitance C1 is provided between the branch points N1 and N2 in the serial arm 4. The capacitance C2 is provided in the parallel arm 53 that connects the branch point N3 in the serial arm 4 and ground. The capacitance C2 is thus provided in the parallel arm 53 that is included in the plurality of parallel arms 5 in which the parallel arm resonators P1, P2, and P4 are not provided. In other words, the capacitance C2 is not provided in the parallel arms 51, 52, and 54 that are included in the plurality of parallel arms 5 in which the parallel arm resonators P1, P2, and P4 are provided.

The three serial arm resonators S1, S3, and S4 are provided in the serial arm 4. In more detail, the serial arm resonator S1 is provided between the first end 2 and the branch point N1 in the serial arm 4. The serial arm resonator S3 is provided between the branch points N2 and N3 in the serial arm 4. The serial arm resonator S4 is provided between the branch points N3 and N4 in the serial arm 4.

The three parallel arm resonators P1, P2, and P4 are respectively provided in the three parallel arms 5 that are included in the four parallel arms 5 in which the capacitance C2 is not provided. In more detail, the parallel arm resonator P1 is provided in the parallel arm 51 connecting the branch point N1 in the serial arm 4 and ground. The parallel arm resonator P2 is provided in the parallel arm 52 connecting the branch point N2 in the serial arm 4 and ground. The parallel arm resonator P4 is provided in the parallel arm 54 connecting the branch point N4 in the serial arm 4 and ground.

A frequency interval between the resonant frequency and the anti-resonant frequency of each of the serial arm resonators S1, S3, and S4 and the parallel arm resonators P1, P2, and P4 is wider than the relevant band.

The respective points of connection with the plurality of parallel arms 5 in the serial arm 4 are defined as the branch points N1 to N4 as described above. The serial arm 4 includes a plurality of serial arm sections L. The plurality of serial arm sections L include a section LI between the first end 2 and the branch point N1 that is included in the plurality of branch points N1 to N4 in the serial arm 4 and that is adjacent to the first end 2, a section L5 between the second end 3 and the branch point N4 that is included in the plurality of branch points N1 to N4 in the serial arm 4 and that is adjacent to the second end 3, and sections L2 to L4 between two adjacent branch points (for example, the branch points N1 and N2, the branch points N2 and N3, and the branch points N3 and N4) that are included in the plurality of branch points N1 to N4. The section L5 between the second end 3 and the branch point N4 that is included in the plurality of branch points N1 to N4 and that is adjacent to the second end 3 in the serial arm 4 is included in the serial arm sections L in this example embodiment but does not have to be included in the serial arm sections L.

The ladder filter 1 includes the one or more capacitances C1 and C2 provided in at least one of the plurality of serial arm sections L and the plurality of parallel arms 5 and the resonators S1, S3, S4, P1, P2, and P4 provided in a remaining one or more of the plurality of serial arm sections L and the plurality of parallel arms 5. At least one serial arm resonator (for example, S1, S3, or S4) of the one or more serial arm resonators S1, S3, and S4 defining and functioning as one or more of the resonators and provided in the serial arm 4 has a corresponding one of resonant frequencies frs1, frs3, and frs4 that is lower than the relevant band. At least one parallel arm resonator (for example, P1, P2, or P4) of the one or more parallel arm resonators P1, P2, and P4 defining and functioning as one or more of the resonators and provided in the parallel arms 5 has a corresponding one of anti-resonant frequencies fap1, fap2, and fap4 that is higher than the relevant band.

In the ladder filter 1, the resonant frequency of each of the three serial arm resonators S1, S3, and S4 is set lower than the relevant band, as described above. The anti-resonant frequency of each of the three parallel arm resonators P1, P2, and P4 is set higher than the relevant band, as described above. The pass band of the ladder filter 1 is thus made narrower than the pass band of the ladder filter in Comparative Example 1 (described later).

In the ladder filter 1, the one or more capacitances C1 and C2 are provided in at least one arm of the plurality of arms including the serial arm 4 and the plurality of parallel arms 5 (for example, the serial arm 4 and the parallel arm 53), as described above. The impedance characteristics of the pass band of the ladder filter 1 are thus set to be neutral between inductive and capacitive. As a result of this, the reflection characteristic of the ladder filter 1 is improved.

As described above, both of the pass band narrowing and reflection characteristic improvement are achieved in the ladder filter 1.

### (3) Ladder Filter Structure

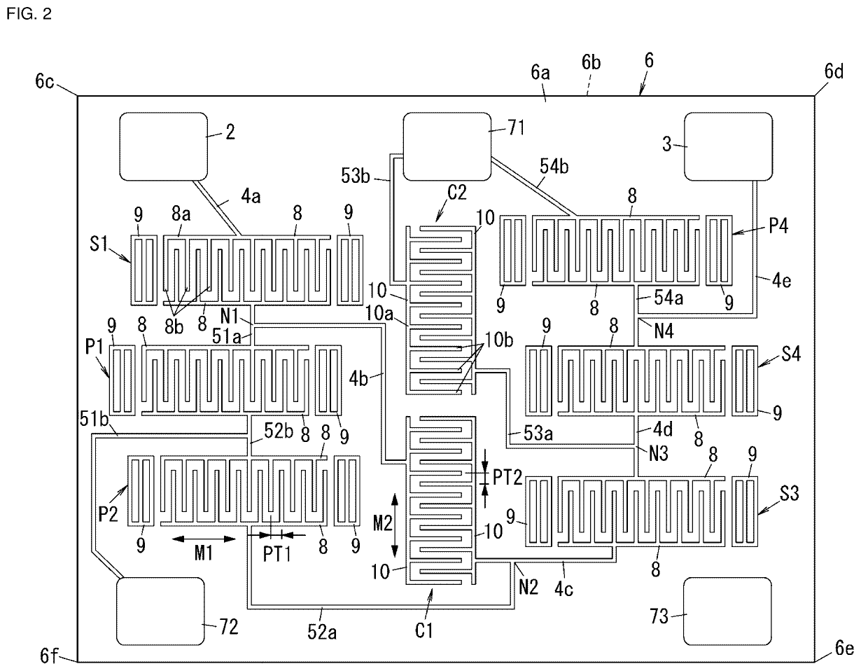

As illustrated in FIG. 2, the ladder filter 1 further includes a substrate 6, and a plurality of (in the example in FIG. 2, three) ground electrodes 71 to 73 in addition to the circuit configuration described above (the serial arm 4, the plurality of parallel arms 5, the first end 2, the second end 3, the two capacitances C1 and C2, the three serial arm resonators S1, S3, and S4, and the three parallel arm resonators P1, P2, and P4).

The substrate 6 is, for example, a piezoelectric substrate. The piezoelectric substrate is made of, for example, piezoelectric single crystal or piezoelectric ceramic. The piezoelectric substrate is, for example, a substrate including a piezoelectric body such as lithium tantalate (LiTaO₃) or lithium niobate (LiNbO₃). The piezoelectric substrate may be, for example, a substrate in which piezoelectric layers made of a piezoelectric material such as lithium tantalate or lithium niobate are stacked on a support substrate made of silicon or the like. A dielectric layer made of, for example, silicon dioxide, silicon nitride, or the like or an electric conductor layer may also be provided between the support substrate and the piezoelectric layer. The substrate 6 is shaped like, for example, a rectangular or substantially rectangular plate in plan view. The substrate 6 includes a first main surface 6a and a second main surface 6b on both sides thereof in a thickness direction. In the present example embodiment, the longer-side direction of the first main surface 6a is a propagation direction of a surface acoustic wave. The circuit configuration and the three ground electrodes 71 to 73 that are described above are provided on the first main surface 6a of the substrate 6.

The first end 2, the second end 3, and the plurality of ground electrodes 71 to 73 are each defined, for example, by a rectangular or substantially rectangular pad electrode.

On the first main surface 6a, the first end 2 is provided, for example, near a corner portion 6c of the first main surface 6a. On the first main surface 6a, the second end 3 is spaced away from the first end 2 in the longer-side direction of the first main surface 6a. In more detail, the second end 3 is provided, for example, near a corner portion 6d of the first main surface 6a. The ground electrode 71 is provided, for example, between the first end 2 and the second end 3 on the first main surface 6a. On the first main surface 6a, the ground electrode 72 is spaced away from the first end 2 in a shorter-side direction of the first main surface 6a. In more detail, the ground electrode 72 is provided, for example, near a corner portion 6f of the first main surface 6a. On the first main surface 6a, the ground electrode 73 is spaced away from the ground electrode 72 in the longer-side direction of the first main surface 6a. In more detail, the ground electrode 73 is provided, for example, in a corner portion 6e of the first main surface 6a.

On the first main surface 6a, the serial arm resonator S1, the parallel arm resonator P1, and the parallel arm resonator P2 are between the first end 2 and the ground electrode 72 (on one side of the first main surface 6a in the longer-side direction). The serial arm resonator S1, the parallel arm resonator P1, and the parallel arm resonator P2 are arranged in this order from the first end 2 toward the ground electrode 72.

On the first main surface 6a, the parallel arm resonator P4, the serial arm resonator S4, and the serial arm resonator S3 are also between the second end 3 and the ground electrode 73. The parallel arm resonator P4, the serial arm resonator S4, and the serial arm resonator S3 are arranged in this order from the second end 3 toward the ground electrode 73.

The capacitance C1 and the capacitance C2 are in the center or approximate center in the longer-side direction of the first main surface 6a (that is, between an area including the serial arm resonator S1, the parallel arm resonator P1, and the parallel arm resonator P2 and an area including the parallel arm resonator P4, the serial arm resonator S4, and the serial arm resonator S3). The capacitance C2 and the capacitance C1 are arranged in this order from the ground electrode 71 side toward an opposite side of the first main surface 6a from the ground electrode 71 in the shorter-side direction of the first main surface 6a.

The serial arm resonators S1, S3, and S4 and the parallel arm resonators P1, P2, and P4 each include a pair of first comb-shaped electrodes 8 (also referred to as an IDT electrode) through which a surface acoustic wave propagates and a pair of reflectors 9 on which the surface acoustic wave is reflected.

The pair of first comb-shaped electrodes 8 include electrode patterns in or on the first main surface 6a of the substrate 6. The paired first comb-shaped electrodes 8 each include a bus bar 8a and a plurality of electrode fingers 8b.

The bus bars 8a of the respective paired first comb-shaped electrodes 8 extend, for example, in the longer-side direction (that is, the surface acoustic wave propagation direction) of the first main surface 6a and are spaced away from each other in the shorter-side direction of the first main surface 6a (that is, a direction orthogonal or substantially orthogonal to the surface acoustic wave propagation direction).

The plurality of electrode fingers 8b of one of the paired first comb-shaped electrodes 8 extend from the bus bar 8a in a direction facing the bus bar 8a of the other one of the first comb-shaped electrodes 8 (that is, in the shorter-side direction of the first main surface 6a). The plurality of electrode fingers 8b of one of the paired first comb-shaped electrodes 8 are positioned between the plurality of electrode fingers 8b of the other first comb-shaped electrode 8. The plurality of electrode fingers 8b of the paired first comb-shaped electrodes 8 are arranged in a longer-side direction of the bus bar 8a (that is, the longer-side direction of the first main surface 6a). An arrangement direction M1 in which the paired first comb-shaped electrodes 8 are arranged thus coincides with the longer-side direction of the bus bar 8a. The arrangement direction M1 is a direction in which the plurality of electrode fingers 8b of the paired first comb-shaped electrodes 8 are arranged. A finger pitch PT1 of the paired first comb-shaped electrodes 8 is set to be the same or substantially the same as a half wavelength of the wavelength of a surface acoustic wave having a predetermined resonant frequency. The finger pitch PT1 is a center-to-center distance between adjacent ones of the electrode fingers 8b.

The pair of reflectors 9 are on both sides of the pair of first comb-shaped electrodes 8 in the longer-side direction of the bus bar 8a. The pair of reflectors 9 include electrode patterns in or on the first main surface 6a of the substrate 6.

The capacitances C1 and C2 each include a pair of second comb-shaped electrodes 10 (also referred to as an IDT electrode). The pair of second comb-shaped electrodes 10 include electrode patterns in or on the first main surface 6a of the substrate 6. The paired second comb-shaped electrodes 10 each include a bus bar 10a and a plurality of electrode fingers 10b.

The bus bars 10a of the respective paired second comb-shaped electrodes 10 extend in the shorter-side direction of the first main surface 6a and are spaced away from each other in the longer-side direction of the first main surface 6a (that is, the surface acoustic wave propagation direction).

The plurality of electrode fingers 10b of one of the paired second comb-shaped electrodes 10 extend from the bus bar 10a in a direction facing the bus bar 10a of the other one of the second comb-shaped electrodes 10. The plurality of electrode fingers 10b of the paired second comb-shaped electrodes 10 are positioned between the plurality of electrode fingers 10b of the other second comb-shaped electrode 10. The plurality of electrode fingers 10b of the paired second comb-shaped electrodes 10 are arranged in a longer-side direction of the bus bar 10a. An arrangement direction M2 in which the paired second comb-shaped electrodes 10 are arranged thus coincides with the longer-side direction of the bus bar 10a. In the present example embodiment, in plan view from the thickness direction of the substrate 6, the arrangement direction M2 of the paired second comb-shaped electrodes 10 is orthogonal or substantially orthogonal to the arrangement direction M1 of the serial arm resonators S1, S3, and S4 and the parallel arm resonators P1, P2, and P4. The arrangement direction M2 is a direction in which the plurality of electrode fingers 10b of the paired second comb-shaped electrodes are arranged.

A finger pitch PT2 of the paired second comb-shaped electrodes 10 is longer or shorter than the finger pitches PT1 of the serial arm resonators S1, S3, and S4 and the parallel arm resonators P1, P2, and P4. In more detail, the finger pitch PT2 of the paired second comb-shaped electrodes 10 is longer than the longest finger pitch PT1 of the finger pitches PT1 of the serial arm resonators S1, S3, and S4 and the parallel arm resonators P1, P2, and P4 or shorter than the shortest finger pitch PT1 of the finger pitches PT1 of the serial arm resonators S1, S3, and S4 and the parallel arm resonators P1, P2, and P4. The finger pitch PT2 is a center-to-center distance between adjacent ones of the electrode fingers 10b.

The serial arm 4 (see FIG. 1) includes electrical paths 4a to 4e. The electrical paths 4a to 4e include electrode patterns in or on the first main surface 6a of the substrate 6. The electrical path 4a connects the first end 2 and one of the first comb-shaped electrodes 8 of the serial arm resonator S1. The electrical path 4b connects the other first comb-shaped electrode 8 of the serial arm resonator S1 and one of the second comb-shaped electrodes 10 of the capacitance C1. The electrical path 4c connects the other second comb-shaped electrode 10 of the capacitance C1 and one of the first comb-shaped electrodes 8 of the serial arm resonator S3. The electrical path 4d connects the other second comb-shaped electrode 10 of the serial arm resonator S3 and one of the first comb-shaped electrodes 8 of the serial arm resonator S4. The electrical path 4e connects the other first comb-shaped electrode 8 of the serial arm resonator S4 and the second end 3.

The parallel arm 51 (see FIG. 1) includes electrical paths 51a and 51b. The electrical paths 51a and 51b include electrode patterns in or on the first main surface 6a of the substrate 6. The electrical path 51a connects one of the first comb-shaped electrodes 8 of the parallel arm resonator P1 and the branch point N1 on the electrical path 4b. The electrical path 51b connects the other first comb-shaped electrode 8 of the parallel arm resonator P1 and the ground electrode 72.

The parallel arm 52 (see FIG. 1) includes electrical paths 52a and 52b. The electrical paths 52a and 52b include electrode patterns in or on the first main surface 6a of the substrate 6. The electrical path 52a connects one of the first comb-shaped electrodes 8 of the parallel arm resonator P2 and the branch point N2 on the electrical path 4c. The electrical path 52b connects the other first comb-shaped electrode 8 of the parallel arm resonator P2 and the ground electrode 72. In the example in FIG. 2, the electrical path 52b has a configuration partially in common with the electrical path 51b.

The parallel arm 53 (see FIG. 1) includes electrical paths 53a and 53b. The electrical paths 53a and 53b include electrode patterns in or on the first main surface 6a of the substrate 6. The electrical path 53a connects one of the second comb-shaped electrodes 10 of the capacitance C2 and the branch point N3 on the electrical path 4d. The electrical path 53b connects the other second comb-shaped electrode 10 of the capacitance C2 and the ground electrode 71.

The parallel arm 54 (see FIG. 1) includes electrical paths 54a and 54b. The electrical paths 54a and 54b include electrode patterns in or on the first main surface 6a of the substrate 6. The electrical path 54a connects one of the first comb-shaped electrodes 8 of the parallel arm resonator P4 and the branch point N4 on the electrical path 4e. The electrical path 54b connects the other first comb-shaped electrode 8 of the parallel arm resonator P4 and the ground electrode 71.

In the ladder filter 1 configured as described above, in plan view from the thickness direction of the substrate 6, the arrangement direction M2 of the capacitances C1 and C2 is inclined (in the example in FIG. 2, orthogonal or substantially orthogonal to) with respect to the arrangement direction M1 of the serial arm resonators S1, S3, and S4 and the parallel arm resonators P1, P2, and P4. The capacitances C1 and C2 may thus be provided by using the pair of second comb-shaped electrodes 10 with the same or substantially the same structure as that of the pair of first comb-shaped electrodes 8 so as to be differentiated from the serial arm resonators S1, S3, and S4 and the parallel arm resonators P1, P2, and P4. In addition, as described above, configuring the capacitances C1 and C2 using the pair of second comb-shaped electrodes 10 enables the capacitances C1 and C2 to be provided by using the manufacturing process of the serial arm resonators S1, S3, and S4 and the parallel arm resonators P1, P2, and P4.

The finger pitch PT1 of each of the three serial arm resonators S1, S3, and S4 is controlled, and thus the resonant frequency of each of the three serial arm resonators S1, S3, and S4 is set lower than the relevant band, as described above. The finger pitch PT1 of each of the three parallel arm resonators P1, P2, and P4 is controlled, the anti-resonant frequency of each of the three parallel arm resonators P1, P2, and P4 is thus set higher than the relevant band, as described above.

### (4) Pass Band Narrowing and Reflection Characteristic of Ladder Filter

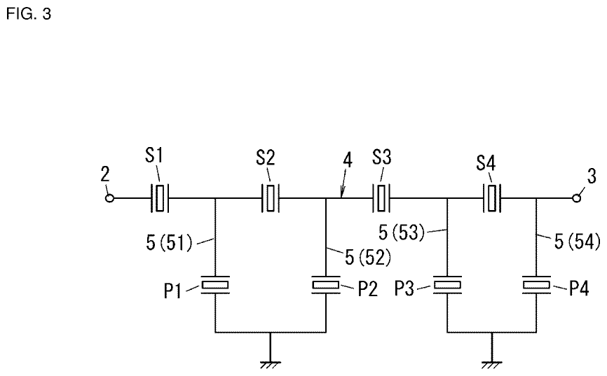

The pass narrowing and the reflection band characteristic of the ladder filter 1 will be described in comparison with Comparative Examples 1 and 2 with reference to FIGS. 3 to 6.

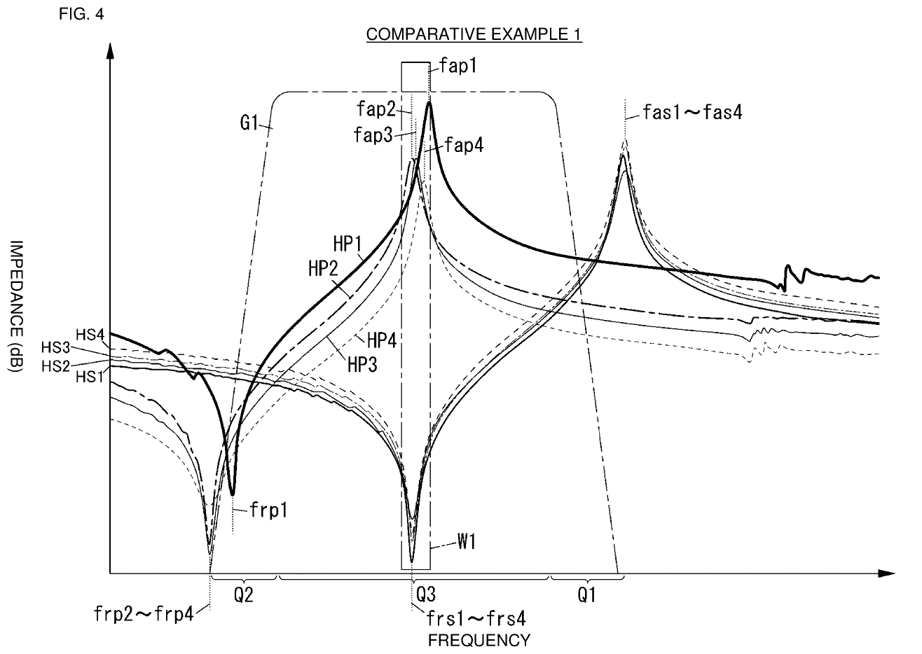

FIGS. 4 to 6 illustrate impedance waveforms of filters in Comparative Example 1 and Comparative Example 2 and the ladder filter 1 according to the present example embodiment. In FIGS. 4 to 6, graphs HS1 to HS4 each represent a corresponding one of the impedance waveforms of the respective serial arm resonators S1 to S4, and graphs HP1 to HP4 each represent a corresponding one of the impedance waveforms of the respective parallel arm resonators P1 to P4.

In FIGS. 4 to 6, references frs1 to frs4 each represent a corresponding one of the resonant frequencies of the serial arm resonators S1 to S4, and references fas1 to fas4 each represent a corresponding one of the anti-resonant frequencies of the serial arm resonators S1 to S4. References frp1 to frp4 each represent a corresponding one of the resonant frequencies of the parallel arm resonators P1 to P4, and references fap1 to fap4 each represent a corresponding one of the anti-resonant frequencies of the parallel arm resonators P1 to P4.

In FIGS. 4 to 6, references G1, G2, and G3 schematically represent respective attenuation characteristics (that is, filter bandpass characteristics) of the filters in Comparative Example 1 and Comparative Example 2 and the ladder filter 1 according to the present example embodiment. In FIGS. 4 to 6, reference W1 is an example of the relevant band (for example, the frequency band in Band30Rx: about 2350 MHz to about 2360 MHz).

### (4-1) Comparative Example 1

Comparative Example 1 illustrates a ladder filter. As illustrated in FIG. 3, in Comparative Example 1, the ladder filter 1 according to the present example embodiment has a configuration in which the capacitance C1 and the capacitance C2 are respectively replaced with a serial arm resonator S2 and a parallel arm resonator P3. In Comparative Example 1, the ladder filter includes four serial arm resonators S1 to S4 and four parallel arm resonators P1 to P4.

As illustrated in FIG. 4, in Comparative Example 1, in the four serial arm resonators S1 to S4, the resonant frequencies frs1 to frs4 match or substantially match, and the anti-resonant frequencies fas1 to fas4 match or substantially match. In the four parallel arm resonators P1 to P4, the resonant frequencies frp1 to frp4 match or substantially match, and the anti-resonant frequencies fap1 to fap4 match or substantially match. The resonant frequencies frs1 to frs4 of the four serial arm resonators S1 to S4 match or substantially match, the anti-resonant frequencies fap1 to fap4 of the four parallel arm resonators P1 to P4 match or substantially match, and the resonant frequencies frs1 to frs4 and the anti-resonant frequencies fap1 to fap4 are included in the relevant band W1.

An attenuation region Q1 with higher frequencies in the attenuation characteristic G1 in Comparative Example 1 includes frequencies near the anti-resonant frequencies fas1 to fas4 of the four serial arm resonators S1 to S4. An attenuation region Q2 with lower frequencies in the attenuation characteristic G1 in Comparative Example 1 includes frequencies near the resonant frequencies frp1 to frp4 of the four parallel arm resonators P1 to P4. A pass band Q3 of the attenuation characteristic G1 in Comparative Example 1 is located between the attenuation region Q1 with higher frequencies and the attenuation region Q2 with lower frequencies. The above-described “pass band” denotes a frequency width at a position about −3 dB lower than the maximum value in the attenuation characteristic G1.

In Comparative Example 1, as described above, the resonant frequencies frs1 to frs4 of the four serial arm resonators S1 to S4 match or substantially match, and the anti-resonant frequencies fap1 to fap4 of the four parallel arm resonators P1 to P4 match or substantially match. Accordingly, if the relevant band W1 is comparatively narrow, there is an issue that the frequency interval between the anti-resonant frequencies fas1 to fas4 of the serial arm resonators S1 to S4 and the resonant frequencies frp1 to frp4 of the parallel arm resonators P1 to P4 in Comparative Example 1 is considerably wider than the relevant band W1. That is, if the relevant band W1 is comparatively narrow, there is an issue that the pass band Q3 in Comparative Example 1 is considerably wider than the relevant band W1.

### (4-2) Comparative Example 2

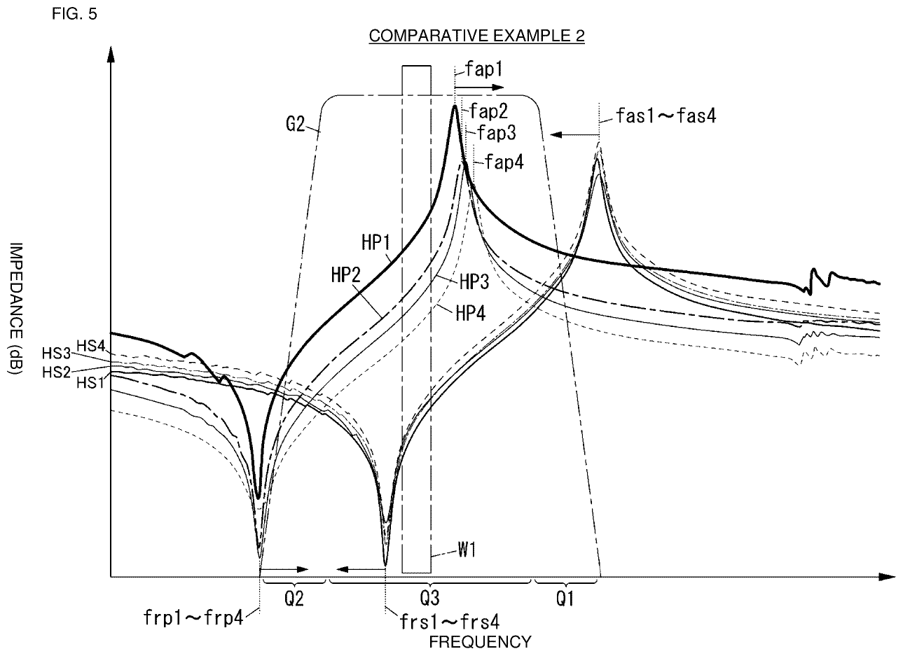

As illustrated in FIG. 5, in Comparative Example 2 as compared with Comparative Example 1, the resonant frequencies frs1 to frs4 of the four serial arm resonators S1 to S4 are lower than the relevant band W1, and the anti-resonant frequencies fap1 to fap4 of the four parallel arm resonators P1 to P4 are higher than the relevant band W1. In Comparative Example 2, in the filter in Comparative Example 1, the resonant frequencies frs1 to frs4 of the four serial arm resonators S1 to S4 transition to a lower frequency region than the relevant band W1, and the anti-resonant frequencies fap1 to fap4 of the four parallel arm resonators P1 to P4 transition to a higher frequency region than the relevant band W1.

This causes the attenuation region Q1 with higher frequencies in the attenuation characteristic G2 in Comparative Example 2 to transition to the lower frequency region than the attenuation region Q1 with higher frequencies in Comparative Example 1 and causes the attenuation region Q2 with lower frequencies in the attenuation characteristic G2 in Comparative Example 2 to transition to the higher frequency region than the attenuation region Q2 with lower frequencies in Comparative Example 1. As a result of this, the frequency interval between the anti-resonant frequencies fas1 to fas4 of the serial arm resonators S1 to S4 and the resonant frequencies frp1 to frp4 of the parallel arm resonators P1 to P4 in Comparative Example 2 is narrower than the frequency interval between the anti-resonant frequencies fas1 to fas4 of the serial arm resonators S1 to S4 and the resonant frequencies frp1 to frp4 of the parallel arm resonators P1 to P4 in Comparative Example 1. This causes the pass band Q3 of the attenuation characteristic G2 in Comparative Example 2 to be narrower than the pass band Q3 in Comparative Example 1. As a result of this, the pass band Q3 in Comparative Example 2 is improved to be prevented from being excessively wider than the relevant band W1. As described above, in Comparative Example 2, the issue in Comparative Example 1 is improved.

However, in Comparative Example 2, as described above, the resonant frequencies frs1 to frs4 of the four serial arm resonators S1 to S4 are lower than the relevant band W1, and the anti-resonant frequencies fap1 to fap4 of the four parallel arm resonators P1 to P4 are higher than the relevant band W1. This causes the impedance characteristics in the pass band Q3 in Comparative Example 2 to be inductive, and as a result of this, the reflection characteristic in Comparative Example 2 is deteriorated. In Comparative Example 2, as described above, there is an issue that the reflection characteristic (that is, impedance matching with a circuit element or the like connected to the ladder filter in Comparative Example 2) is deteriorated because the impedance characteristics of the pass band Q3 become inductive.

### (4-3) Pass Band Narrowing and Reflection Characteristic Improvement in Ladder Filter According to Example Embodiment

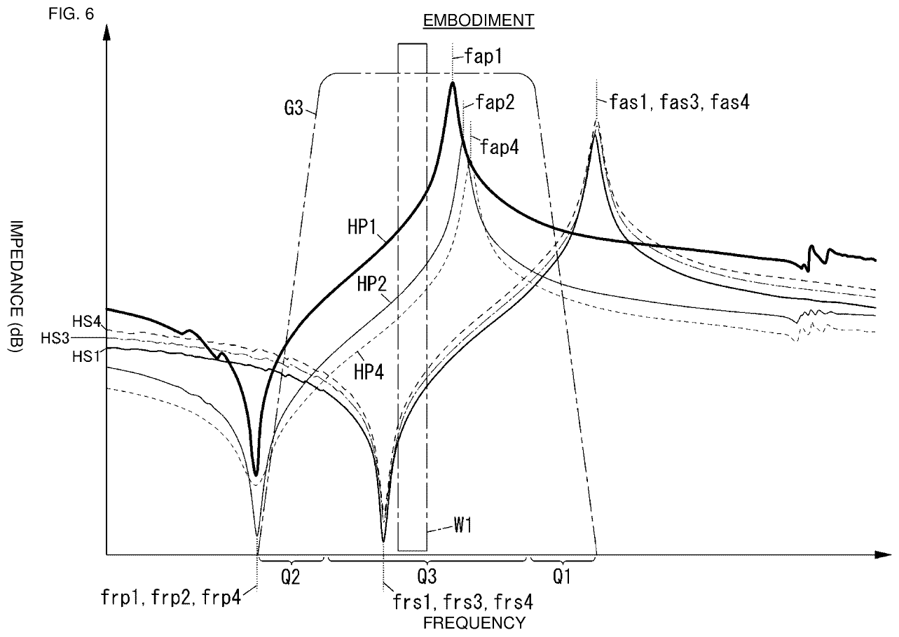

As illustrated in FIG. 1, the ladder filter 1 according to the present example embodiment has a configuration in which in the configuration in Comparative Example 2 (see FIG. 3), at least one resonator of the four serial arm resonators S1 to S4 and the four parallel arm resonators P1 to P4 (for example, the serial arm resonator S2 and the parallel arm resonator P3) is replaced with a capacitance (the capacitance C1 or C2). This causes the impedance characteristics of the pass band Q3 of the ladder filter 1 according to the present example embodiment (see FIG. 6) to transition from the inductive characteristics to the characteristics that are neutral between inductive and capacitive, and as a result of this, the reflection characteristic of the ladder filter 1 according to the present example embodiment is improved. As described above, in the ladder filter 1 according to the present example embodiment, the issue in Comparative Example 2 is improved. The example in FIG. 1 illustrates the case where the serial arm resonator S2 and the parallel arm resonator P3 are replaced with the capacitances C1 and C2 in Comparative Example 2 (see FIG. 3). However, only at least one serial arm resonator (for example, the serial arm resonator S2) of the plurality of serial arm resonators S1 to S4 and the plurality of parallel arm resonators P1 to P4 in Comparative Example 2 may be replaced with the capacitance C1. Only at least one parallel arm resonator (for example, the parallel arm resonator P3) of the plurality of serial arm resonators S1 to S4 and the plurality of parallel arm resonators P1 to P4 may also be replaced with the capacitance C2. A configuration in which all resonators of the four serial arm resonators S1 to S4 and the four parallel arm resonators P1 to P4 are replaced with capacitances is excluded.

As illustrated in FIG. 6, in the ladder filter according to the present example embodiment, similar to Comparative Example 2, the resonant frequencies frs1, frs3, and frs4 of the three serial arm resonators S1, S3, and S4 are lower than the relevant band W1, and the anti-resonant frequencies fap1, fap2, and fap4 of the three parallel arm resonators P1, P2, and P4 are higher than the relevant band W1. This causes, as in Comparative Example 2, the attenuation region Q1 with higher frequencies in the attenuation characteristic G3 of the ladder filter 1 according to the present example embodiment to transition to a lower frequency region than the attenuation region Q1 with higher frequencies in Comparative Example 1 and causes the attenuation region Q2 with lower frequencies in the attenuation characteristic G3 of the ladder filter 1 according to the present example embodiment to transition to a higher frequency region than the attenuation region Q2 with lower frequencies in Comparative Example 1. As a result of this, the frequency interval between the anti-resonant frequencies fas1, fas3, and fas4 of the serial arm resonators S1, S3, and S4 and the resonant frequencies frp1, frp2, and frp4 of the parallel arm resonators P1, P2, and P4 in the ladder filter 1 according to the present example embodiment is narrower than the frequency interval between the anti-resonant frequencies fas1 to fas4 of the serial arm resonators S1 to S4 and the resonant frequencies frp1 to frp4 of the parallel arm resonators P1 to P4 in Comparative Example 1. The pass band Q3 in the attenuation characteristic G3 of the ladder filter 1 according to the present example embodiment is thus narrower than the pass band Q3 in Comparative Example 1. As described above, in the ladder filter 1 according to the present example embodiment, as in Comparative Example 2, the pass band Q3 is improved to be prevented from being excessively wider than the relevant band W1.

As described above, in the ladder filter 1 according to the present example embodiment, the pass band Q3 is narrowed for the relevant band W1, and the reflection characteristic is improved.

### (4-4) Comparison in Attenuation Characteristic (Filter Bandpass Characteristic) Among Present Example Embodiment, Comparative Example 1, and Comparative Example 2

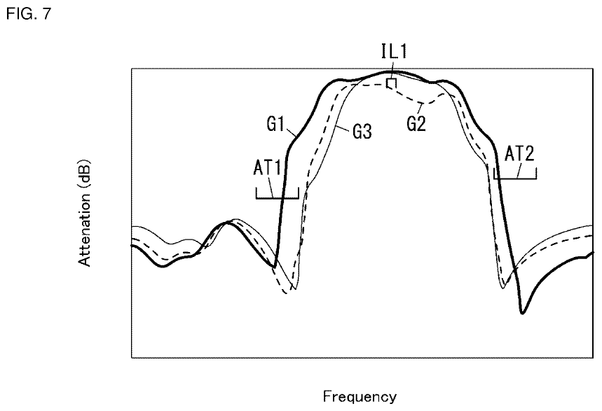

In FIG. 7, the graph G1 represents an attenuation characteristic in Comparative Example 1, the graph G2 represents an attenuation characteristic in Comparative Example 2, and the graph G3 represents an attenuation characteristic of the ladder filter 1 according to the present example embodiment. For a band pass filter allowing a signal in the relevant band W1 to pass therethrough, reference IL1 represents a characteristic for an insertion loss (the lower limit of attenuation), reference AT1 represents a characteristic for attenuation at lower frequencies, and reference AT2 represents a characteristic for attenuation at higher frequencies.

As illustrated in FIG. 7, the attenuation characteristic G1 in Comparative Example 1 satisfies the characteristic IL1 for the insertion loss in the pass band. The attenuation characteristic G1 thus exceeds the characteristic IL1 for the insertion loss in the pass band. However, in the attenuation characteristic G1 in Comparative Example 1, each of the attenuation at lower frequencies and the attenuation at higher frequencies does not satisfy a corresponding one of the characteristics AT1 and AT2. That is, in the attenuation characteristic G1, the attenuation at lower frequencies does not fall below the characteristic AT1 in the entire range of the characteristic AT1, and the attenuation at higher frequencies does not fall below the characteristic AT2 in the entire range of the characteristic AT2.

In contrast, in the attenuation characteristic G2 in Comparative Example 2, both of the attenuation at lower frequencies and the attenuation at higher frequencies satisfy the characteristics AT1 and AT2. That is, in the attenuation characteristic G2 in Comparative Example 2, the attenuation at lower frequencies falls below the characteristic AT1 in the entire range of the characteristic AT1, and the attenuation at higher frequencies falls below the characteristic AT2 in the entire range of the characteristic AT2. As a result of this, the attenuation region with higher frequencies in the attenuation characteristic G2 in Comparative Example 2 transitions to a lower frequency region than the attenuation region with higher frequencies in the attenuation characteristic G1 in Comparative Example 1. The attenuation region with higher frequencies in the attenuation characteristic G2 in Comparative Example 2 transitions to a higher frequency region than the attenuation region with lower frequencies in the attenuation characteristic G1 in Comparative Example 1. That is, the pass band in the attenuation characteristic G2 in Comparative Example 2 is narrower than the pass band in the attenuation characteristic G1 in Comparative Example 1.

However, the attenuation characteristic G2 in Comparative Example 2 does not satisfy the characteristic IL1 for the insertion loss in the pass band. The attenuation characteristic G2 in Comparative Example 2 thus falls below the characteristic IL1 for the insertion loss in the pass band. This is attributed to the fact that the impedance characteristics in the pass band become inductive in Comparative Example 2 (that is, the reflection characteristic in Comparative Example 2 is deteriorated).

In contrast, in the attenuation characteristic G3 of the ladder filter 1 according to the present example embodiment, like the attenuation characteristic G2 in Comparative Example 2, both of the attenuation at lower frequencies and the attenuation at higher frequencies satisfy the characteristics AT1 and AT2. That is, the attenuation region with higher frequencies in the attenuation characteristic G3 of the ladder filter 1 according to the present example embodiment transitions to the lower frequency region than the attenuation region with higher frequencies in the attenuation characteristic G1 in Comparative Example 1. The attenuation region with lower frequencies in the attenuation characteristic G3 of the ladder filter 1 according to the present example embodiment transitions to the higher frequency region than the attenuation region with lower frequencies in the attenuation characteristic G1 in Comparative Example 1. As a result of this, the pass band in the attenuation characteristic G3 of the ladder filter 1 according to the present example embodiment is narrower than the pass band in the attenuation characteristic G1 in Comparative Example 1.

The attenuation characteristic G3 of the ladder filter 1 according to the present example embodiment satisfies the characteristic IL1 for the insertion loss in the pass band. In the ladder filter 1 according to the present example embodiment, the impedance characteristics in the pass band thus transition to properties that are neutral between capacitive and inductive. The reflection characteristic of the ladder filter 1 according to the present example embodiment is thus improved as compared with Comparative Example 2.

As described above, in the ladder filter 1 according to the present example embodiment, the pass band is narrower than that in Comparative Example 1, and the reflection characteristic is improved as compared with Comparative Example 2.

### (5) Specific Examples of Relevant Band

The ladder filter 1 according to the present example embodiment has a comparatively narrow band as the relevant band W1. Specifically, for example, Band30Rx, Band30Tx, Band34TRx, and Band53TRx of the bands specified in 3GPP (registered trademark) are provided as the relevant band W1. The relevant band W1 is not limited to the bands exemplified above.

### (6) Advantageous Effects

The ladder filter 1 according to the present example embodiment includes the one or more serial arm resonators S1, S3, and S4 and the one or more parallel arm resonators P1, P2, and P4. The one or more serial arm resonators S1, S3, and S4 are provided in the serial arm 4 that connects the first end 2 and the second end 3. The one or more parallel arm resonators P1, P2, and P4 are provided in the plurality of parallel arms 5 that connect the serial arm 4 and ground. The resonant frequency frs1, frs3, or frs4 of the at least one serial arm resonator S1, S3, or S4 of the one or more serial arm resonators S1, S3, and S4 is lower than the relevant band W1. The anti-resonant frequency fap1, fap2, or fap4 of the at least one parallel arm resonator P1, P2, or P4 of the one or more parallel arm resonators P1, P2, and P4 is higher than the relevant band W1. The ladder filter 1 further includes the one or more capacitances C1 and C2 provided in at least one arm of a plurality of arms including the serial arm 4 and the plurality of parallel arms 5. The one or more capacitances C1 and C2 are not provided in the parallel arms 51, 52, and 54 that are included in the plurality of parallel arms 5 in which the one or more parallel arm resonators P1, P2, and P4 are provided.

According to this configuration, the resonant frequencies frs1, frs3, and frs4 of the serial arm resonators S1, S3, and S4 are lower than the relevant band W1, and the anti-resonant frequencies fap1, fap2, and fap4 of the parallel arm resonators P1, P2, and P4 are higher than the relevant band W1. This causes the anti-resonant frequencies fas1, fas3, and fas4 (that is, frequencies included the attenuation region Q1 with higher frequencies in the attenuation characteristic G3 of the ladder filter 1 of the serial arm resonators S1, S3, and S4) to be lower than those of the ladder filter in Comparative Example 1 and causes the resonant frequencies frp1, frp2, and frp4 of the parallel arm resonators P1, P2, and P4 (that is, frequencies included in the attenuation region Q2 with lower frequencies in the attenuation characteristic G3 of the ladder filter 1) to be higher. The pass band Q3 in the attenuation characteristic G3 of the ladder filter 1 may thus be made narrower than the pass band Q3 in the attenuation characteristic G1 in Comparative Example 1.

The one or more capacitances C1 and C2 are provided in at least one arm of the plurality of arms. Accordingly, the impedance characteristics of the pass band Q3 of the ladder filter 1 may be set to be characteristics that are neutral between inductive and capacitive. The reflection characteristic of the ladder filter 1 may thus be improved. The case where the one or more capacitances C1 and C2 are provided in all of the plurality of arms is excluded.

As described above, both of the band narrowing of the pass band Q3 and the reflection characteristic improvement in the ladder filter 1 are achieved.

### (7) Modifications

Modifications of example embodiments of the present invention described above will be described.

### (7-1) Modification 1

The example embodiments described above have exemplified a case where the arrangement direction M2 of the capacitances C1 and C2 in plan view from the thickness direction of the substrate 6 is orthogonal or substantially orthogonal to the arrangement direction M1 of the serial arm resonators S1, S3, and S4 and the parallel arm resonators P1, P2, and P4 (that is, inclined by about 90 degrees).

However, the arrangement direction of the M2 capacitances C1 and C2 is not limited to the case where the arrangement direction M2 is orthogonal or substantially orthogonal to the arrangement direction M1 of the serial arm resonators S1, S3, and S4 and the parallel arm resonators P1, P2, and P4. For example, it suffices that the arrangement direction M2 of the capacitances C1 and C2 is inclined by about ten degrees or more with respect to the arrangement direction M1 of the serial arm resonators S1, S3, and S4 and the parallel arm resonators P1, P2, and P4. The capacitances C1 and C2 may thus be differentiated from the serial arm resonators S1, S3, and S4 and the parallel arm resonators P1, P2, and P4.

It suffices that the arrangement direction M2 of the capacitances C1 and C2, for example, inclined by about 45 degrees or more with respect to the arrangement direction M1 of the serial arm resonators S1, S3, and S4 and the parallel arm resonators P1, P2, and P4. The capacitances C1 and C2 may thus be differentiated from the serial arm resonators S1, S3, and S4 and the parallel arm resonators P1, P2, and P4 more reliably.

### (7-2) Modification 2

The example embodiments described above have exemplified a case where the resonant frequencies frs1, frs3, and frs4 of all of the three serial arm resonators S1, S3, and S4 are made lower than the relevant band W1. However, for example, at least one resonant frequency of the three serial arm resonators S1, S3, and S4 may be made lower than the relevant band W1. In this case, the serial arm resonator to be made lower than the relevant band W1 of the three serial arm resonators S1, S3, and S4 may at least include the serial arm resonator having the lowest resonant frequency of the three serial arm resonators S1, S3, and S4. The serial arm resonator to be made lower than the relevant band W1 of the three serial arm resonators S1, S3, and S4 may be only the serial arm resonator having the lowest resonant frequency of the three serial arm resonators S1, S3, and S4.

According to Modification 2, similar to the example embodiments described above, as compared with the case where the resonant frequencies frs1, frs3, and frs4 of all of the serial arm resonators S1, S3, and S4 are not made lower than the relevant band W1 (for example, as compared with Comparative Example 1), the attenuation region with higher frequencies of the ladder filter 1 according to Modification 2 may be caused to transition to a lower frequency region. As a result of this, similar to the example embodiments described above, the pass band of the ladder filter 1 according to Modification 2 may be narrowed.

### (7-3) Modification 3

The example embodiments described above have exemplified a case where the resonant frequencies frp1, frp2, and frp4 of all of the three parallel arm resonators P1, P2, and P4 are made higher than the relevant band W1. However, for example, at least one resonant frequency of the three parallel arm resonators P1, P2, and P4 may be made higher than the relevant band W1. In this case, the parallel arm resonator to be made higher than the relevant band W1 of the three parallel arm resonators P1, P2, and P4 may at least include the parallel arm resonator having the highest resonant frequency of the three parallel arm resonators P1, P2, and P4. The parallel arm resonator to be made higher than the relevant band W1 of the three parallel arm resonators P1, P2, and P4 may also be only the parallel arm resonator having the highest resonant frequency of the three parallel arm resonators P1, P2, and P4.

According to Modification 3, similar to the example embodiments described above, as compared with the case where the resonant frequencies frp1, frp2, and frp4 of all of the parallel arm resonators P1, P2, and P4 are not made higher than the relevant band W1 (for example, Comparative Example 1), the attenuation region with lower frequencies of the ladder filter 1 according to Modification 3 may be caused to transition to a higher frequency region. As a result of this, similar to the example embodiments described above, the pass band of the ladder filter 1 according to Modification 3 may be narrowed.

### (7-4) Modification 4

The example embodiments described above have exemplified a case where the capacitances C1 and C2 each include the pair of second comb-shaped electrodes 10. However, the capacitances C1 and C2 are not limited to the case where the capacitances C1 and C2 each include the pair of second comb-shaped electrodes 10. For example, the capacitances C1 and C2 may have a metal-insulator-metal (MIM) structure in which an insulating layer is sandwiched between metals. With this configuration, similar to the example embodiments described above, the impedance characteristics of the pass band of the ladder filter 1 according to Modification 4 may be improved from the inductive characteristics to the characteristics that are neutral between inductive and capacitive.

### (7-5) Other Modifications

The example embodiments described above are merely some of various example embodiments of the present invention. Various changes may be made to the example embodiments described above depending on design differences or the like, as long as the advantageous effects example embodiments of the present invention are achieved. Mutually different components in example embodiments and modifications thereof may be combined appropriately.

A ladder filter (1) according to an example embodiment of the present invention includes one or more serial arm resonators (S1, S3, and S4), and one or more parallel arm resonators (P1, P2, and P4). The one or more serial arm resonators (S1, S3, and S4) are provided in a serial arm (4) that connects a first end (2) and a second end (3). The one or more parallel arm resonators (P1, P2, and P4) are provided in a plurality of parallel arms (5) that connect the serial arm (4) and ground. A frequency interval between a resonant frequency and an anti-resonant frequency of each of the one or more serial arm resonators (S1, S3, and S4) and the one or more parallel arm resonators (P1, P2, and P4) is wider than a relevant band. The resonant frequency (frs1, frs3, or frs4) of at least one serial arm resonator (S1, S3, or S4) of the one or more serial arm resonators (S1, S3, and S4) is lower than the relevant band (W1). The anti-resonant frequency (fap1, fap2, or fap4) of at least one parallel arm resonator (P1, P2, or P4) of the one or more parallel arm resonators (P1, P2, and P4) is higher than the relevant band (W1). The ladder filter (1) further includes one or more capacitances (C1 and C2) provided in at least one arm of a plurality of arms including the serial arm (4) and the plurality of parallel arms (5). The one or more capacitances (C1 and C2) are not provided in one or more parallel arms (51, 52, and 54) that are included in the plurality of parallel arms (5) in which the one or more parallel arm resonators (P1, P2, and P4) are provided.

According to this configuration, the resonant frequencies (frs1, frs3, and frs4) of the serial arm resonators (S1, S3, S4) are lower than the relevant band (W1), and the anti-resonant frequencies (fap1, fap2, and fap4) of the parallel arm resonators (P1, P2, P4) are higher than the relevant band (W1). This causes the anti-resonant frequencies (fas1, fas3, and fas4) of the serial arm resonators (S1, S3, S4) to be lower than those in Comparative Example 1 and causes the resonant frequencies (frp1, frp2, and frp4) of the parallel arm resonators (P1, P2, P4) to be higher. The pass band (Q3) of the ladder filter (1) may thus be made narrower than that of the ladder filter in Comparative Example 1.

The one or more capacitances (C1 and C2) are provided in at least one arm of the plurality of arms. Accordingly, the impedance characteristics of the pass band (Q3) of the ladder filter (1) may be set to be neutral between inductive and capacitive. The reflection characteristic of the ladder filter (1) may thus be improved.

As described above, both of the band narrowing of the pass band (Q3) and the reflection characteristic improvement in the ladder filter (1) may be achieved.

In a ladder filter (1) according to an example embodiment of the present invention, the one or more capacitances (C1 and C2) include a first capacitance (C1) provided in the serial arm (4) and a second capacitance (C2) provided in one of the plurality of parallel arms (5).

According to this configuration, the impedance characteristics of the pass band (Q3) of the ladder filter (1) may be set to be neutral between inductive and capacitive by including the two capacitances (the first capacitance (C1) and the second capacitance (C2)). The reflection characteristic of the ladder filter (1) may thus be improved.

A ladder filter (1) according to an example embodiment of the present invention includes a serial arm (4) that connects a first end (2) and a second end (3) and a plurality of parallel arms (5) connected between the serial arm (4) and ground. Points of connection with the plurality of parallel arms (5) are defined as a plurality of branch points (N1 to N4) included in the serial arm (4). The serial arm (4) includes a plurality of serial arm sections (L). The plurality of serial arm sections (L) include a section (L1) between the first end (2) and a branch point (N1) included in the plurality of branch points (N1 to N4) in the serial arm (4) and that is adjacent to the first end (2), a section (L5) between the second end (3) and a branch point (N4) included in the plurality of branch points (N1 to N4) in the serial arm (4) and that is adjacent to the second end (3), and sections (L2 to L4) between two adjacent branch points (the branch point (N1) and the branch point (N2), the branch points (N2) and the branch point (N3), and the branch points (N3) and the branch point (N4)) that are included in the plurality of branch points (N1 to N4). The ladder filter (1) includes one or more capacitances (C1 and C2) provided in at least one of the plurality of serial arm sections (L) and the plurality of parallel arms (5), and one or more resonators (S1, S3, S4, P1, P2, and P4) in remaining one or more of the plurality of serial arm sections (L) and the plurality of parallel arms (5). A frequency interval between a resonant frequency and an anti-resonant frequency of the one or more resonators (S1, S3, S4, P1, P2, and P4) is wider than a relevant band (W1). The resonant frequency (frs1, frs3, or frs4) of at least one serial arm resonator (S1, S3, or S4) of one or more serial arm resonators (S1, S3, and S4) defining and functioning as one or more of the resonators and provided in the serial arm (4) is lower than the relevant band (W1). The anti-resonant frequency (fap1, fap2, or fap4) of at least one parallel arm resonator (P1, P2, or P4) of one or more parallel arm resonators (P1, P2, and P4) defining and functioning as one or more of the resonators and provided in the parallel arms (5) is higher than the relevant band (W1).

According to this configuration, the resonant frequencies (frs1, frs3, and frs4) of the serial arm resonators (S1, S3, S4) are lower than the relevant band (W1), and the anti-resonant frequencies (fap1, fap2, and fap4) of the parallel arm resonators (P1, P2, P4) are higher than the relevant band (W1). This causes the anti-resonant frequencies (fas1, fas3, and fas4) of the serial arm resonators (S1, S3, S4) to be lower than those in Comparative Example 1 and causes the resonant frequencies (frp1, frp2, and frp4) of the parallel arm resonators (P1, P2, P4) to be higher. The pass band (Q3) of the ladder filter (1) may thus be made narrower than the pass band (Q3) of the ladder filter in Comparative Example 1.

The one or more capacitances (C1 and C2) are provided in at least one of the plurality of serial arm sections (L) and the plurality of parallel arms (5). The impedance characteristics of the pass band (Q3) of the ladder filter (1) may thus be set to be neutral between inductive and capacitive. The reflection characteristic of the ladder filter (1) may thus be improved.

As described above, both of the band narrowing of the pass band (Q3) and the reflection characteristic improvement in the ladder filter (1) may be achieved.

In a ladder filter (1) according to an example embodiment of the present invention, the one or more capacitances (C1 and C2) include a first capacitance (C1) provided in one of the plurality of serial arm sections (L) and a second capacitance (C2) provided in one of the plurality of parallel arms (5).

According to this configuration, the impedance characteristics of the pass band (Q3) of the ladder filter (1) may be set to be neutral between inductive and capacitive by including the two capacitances (the first capacitance (C1) and the second capacitance (C2)). The reflection characteristic of the ladder filter (1) may thus be improved.

In a ladder filter (1) according to an example embodiment of the present invention, the at least one serial arm resonator (S1, S3, or S4) includes a serial arm resonator with a lowest resonant frequency of the one or more serial arm resonators (S1, S3, and S4).

According to this configuration, an attenuation region (Q1) with higher frequencies in an attenuation characteristic (G3) of the ladder filter (1) may be caused to transition to a lower frequency region effectively.

In a ladder filter (1) according to an example embodiment of the present invention, the at least one serial arm resonator (S1, S3, or S4) includes all of the one or more serial arm resonators (S1, S3, and S4).

According to this configuration, the attenuation region (Q1) with higher frequencies in the attenuation characteristic (G3) of the ladder filter (1) may be caused to transition to a lower frequency region further effectively.

In a ladder filter (1) according to an example embodiment of the present invention, the at least one parallel arm resonator (P1, P2, or P4) includes a parallel arm resonator having a highest resonant frequency of the one or more parallel arm resonators (P1, P2, and P4).

According to this configuration, an attenuation region (Q2) with lower frequencies in the attenuation characteristic (G3) of the ladder filter (1) may be caused to transition to a higher frequency region effectively.

In the ladder filter (1) according to an example embodiment of the present invention, the at least one parallel arm resonator (P1, P2, or P4) includes all of the one or more parallel arm resonators (P1, P2, and P4).

According to this configuration, the attenuation region (Q2) with lower frequencies in the attenuation characteristic (G3) of the ladder filter (1) may be caused to transition to a higher frequency region further effectively.

A ladder filter (1) according to an example embodiment of the present invention further includes a substrate (6) including the one or more capacitances (C1 and C2), the one or more serial arm resonators (S1, S3, and S4), and the one or more parallel arm resonators (P1, P2, and P4). The one or more serial arm resonators (S1, S3, and S4) and the one or more parallel arm resonators (P1, P2, and P4) each include a pair of first comb-shaped electrodes (8) arranged in the same arrangement direction (M1). The one or more capacitances (C1 and C2) each include a pair of second comb-shaped electrodes (10). In plan view from a thickness direction of the substrate (6), an arrangement direction (M2) of the pair of second comb-shaped electrodes (10) is inclined with respect to the arrangement direction (M1) of the pair of first comb-shaped electrodes (8).

According to this configuration, the arrangement direction (M2) of the pair of second comb-shaped electrodes (10) is inclined with respect to the arrangement direction (M1) of the pair of first comb-shaped electrodes (8). The capacitances (C1 and C2) may thus be provided by the pair of second comb-shaped electrodes (10) having the same structure as that of the first comb-shaped electrode (8) so as to be differentiated from the serial arm resonators (S1, S3, S4) and the parallel arm resonators (P1, P2, and P4). In addition, as described above, configuring the capacitances (C1 and C2) by using the pair of second comb-shaped electrodes (10) enables the capacitances (C1 and C2) to be formed by using the manufacturing process of the serial arm resonators (S1, S3, S4) and the parallel arm resonators (P1, P2, P4).

In a ladder filter (1) according to an example embodiment of the present invention, a finger pitch (PT2) of the pair of second comb-shaped electrodes (10) is longer or shorter than a finger pitch (PT1) of the pair of first comb-shaped electrodes (8).

According to this configuration, resonance of an unwanted wave occurring on the capacitances (C1 and C2) with an unwanted wave occurring on the serial arm resonators (S1, S3, S4) or the parallel arm resonators (P1, P2, P4) may be reduced or prevented. As a result of this, the occurrence of a ripple in the pass band (Q3) of the ladder filter (1) due to the resonance may be reduced or prevented.

In a ladder filter (1) according to an example embodiment of the present invention, the substrate (6) is a piezoelectric substrate.

According to this configuration, resonance of a bulk wave (unwanted wave) leaking from the capacitances (C1 and C2) with a bulk wave (unwanted wave) leaking from the serial arm resonators (S1, S3, S4) or the parallel arm resonators (P1, P2, P4) may be reduced or prevented. As a result of this, the occurrence of a ripple in the pass band (Q3) of the ladder filter (1) due to the resonance may be reduced or prevented.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A ladder filter comprising:
one or more serial arm resonators provided in a serial arm connecting a first end and a second end of the ladder filter; and
one or more parallel arm resonators provided in a plurality of parallel arms connecting the serial arm and ground; wherein
a frequency interval between a resonant frequency and an anti-resonant frequency of each of the one or more serial arm resonators and the one or more parallel arm resonators is wider than a relevant band;
the resonant frequency of at least one serial arm resonator of the one or more serial arm resonators is lower than the relevant band;
the anti-resonant frequency of at least one parallel arm resonator of the one or more parallel arm resonators is higher than the relevant band; and
the ladder filter further includes:
one or more capacitances provided in at least one arm of a plurality of arms including the serial arm and the plurality of parallel arms and not connected in parallel to any of the one or more series arm resonators or the one or more parallel arm resonators; wherein
the one or more capacitances are not provided in one or more parallel arms of the plurality of parallel arms in which the one or more parallel arm resonators are provided.

2. The ladder filter according to claim 1, wherein
the one or more capacitances include:
a first capacitance provided in the serial arm; and
a second capacitance provided in one of the plurality of parallel arms.

3. The ladder filter according to claim 1, wherein the at least one serial arm resonator includes a serial arm resonator with a lowest resonant frequency of the one or more serial arm resonators.

4. The ladder filter according to claim 3, wherein the at least one serial arm resonator includes all of the one or more serial arm resonators.

5. The ladder filter according to claim 1, wherein the at least one parallel arm resonator includes a parallel arm resonator with a highest resonant frequency of the one or more parallel arm resonators.

6. The ladder filter according to claim 5, wherein the at least one parallel arm resonator includes all of the one or more parallel arm resonators.

7. The ladder filter according to claim 1, further comprising:
a substrate including the one or more capacitances, the one or more serial arm resonators, and the one or more parallel arm resonators; wherein
the one or more serial arm resonators and the one or more parallel arm resonators each include a pair of first comb-shaped electrodes provided in a same arrangement direction;
the one or more capacitances each include a pair of second comb-shaped electrodes; and
in plan view from a thickness direction of the substrate, an arrangement direction of the pair of second comb-shaped electrodes is inclined with respect to the arrangement direction of the pair of first comb-shaped electrodes.

8. The ladder filter according to claim 7, wherein a finger pitch of the pair of second comb-shaped electrodes is longer or shorter than a finger pitch of the pair of first comb-shaped electrodes.

9. The ladder filter according to claim 8, wherein the substrate is a piezoelectric substrate.

10. A ladder filter comprising:
a serial arm connecting a first end and a second end of the ladder filter; and
a plurality of parallel arms connected between the serial arm and ground; wherein
points of connection with the plurality of parallel arms are defined as a plurality of branch points, the points of connection being included in the serial arm;
the serial arm includes a plurality of serial arm sections;
the plurality of serial arm sections include:
a first section between the first end and a first branch point of the plurality of branch points in the serial arm and that is adjacent to the first end;
a second section between the second end and a second branch point of the plurality of branch points in the serial arm and that is adjacent to the second end; and
a third section between two adjacent branch points of the plurality of branch points;
the ladder filter further includes:
one or more capacitances provided in at least one of the plurality of serial arm sections and the plurality of parallel arms and not connected in parallel to any resonators; and
one or more resonators provided in a remaining one or more of the plurality of serial arm sections and the plurality of parallel arms;
a frequency interval between a resonant frequency and an anti-resonant frequency of the one or more resonators is wider than a relevant band;
the resonant frequency of at least one serial arm resonator of one or more serial arm resonators defining and functioning as one or more of the resonators and provided in the serial arm is lower than the relevant band; and
the anti-resonant frequency of at least one parallel arm resonator of one or more parallel arm resonators defining and functioning as one or more of the resonators and provided in the parallel arms is higher than the relevant band.

11. The ladder filter according to claim 10, wherein
the one or more capacitances include:
a first capacitance provided in one of the plurality of serial arm sections; and
a second capacitance provided in one of the plurality of parallel arms.

12. The ladder filter according to claim 10, wherein the at least one serial arm resonator includes a serial arm resonator with a lowest resonant frequency of the one or more serial arm resonators.

13. The ladder filter according to claim 12, wherein the at least one serial arm resonator includes all of the one or more serial arm resonators.

14. The ladder filter according to claim 10, wherein the at least one parallel arm resonator includes a parallel arm resonator with a highest resonant frequency of the one or more parallel arm resonators.

15. The ladder filter according to claim 14, wherein the at least one parallel arm resonator includes all of the one or more parallel arm resonators.

16. The ladder filter according to claim 10, further comprising:
a substrate including the one or more capacitances, the one or more serial arm resonators, and the one or more parallel arm resonators; wherein
the one or more serial arm resonators and the one or more parallel arm resonators each include a pair of first comb-shaped electrodes provided in a same arrangement direction;
the one or more capacitances each include a pair of second comb-shaped electrodes; and
in plan view from a thickness direction of the substrate, an arrangement direction of the pair of second comb-shaped electrode is inclined with respect to the arrangement direction of the pair of first comb-shaped electrodes.

17. The ladder filter according to claim 16, wherein a finger pitch of the pair of second comb-shaped electrodes is longer or shorter than a finger pitch of the pair of first comb-shaped electrodes.

18. The ladder filter according to claim 17, wherein the substrate is a piezoelectric substrate.
